(19) United States
(12) Patent Application Publication
(10) Pub. No.: US 2009/0219186 A1
(43) Pub. Date: Sep. 3, 2009

(54) FILTER CIRCUIT, RECEIVER USING THE SAME, AND FILTERING METHOD USING THE SAME

(76) Inventors: Hiroaki Ishihara, Tokyo (JP); Masahiro Hosoya, Kawasaki-shi (JP); Hidenori Okuni, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/366,712

(22) Filed: Feb. 6, 2009

(30) Foreign Application Priority Data
Feb. 29, 2008 (JP) P2008-050945

(51) Int. Cl. H03M 1/12

(52) U.S. Cl. 341/155

(57) ABSTRACT

According to an aspect of the present invention, there is provided a filter circuit including: an ADC that converts a first analog signal into a first digital signal; a digital filter that extracts an interference component from the first digital signal and generates a second digital signal; a DAC that converts the second digital signal into a second analog signal; a delayer that delays the first analog signal based on a delay caused in the second analog signal and generates a delayed first analog signal; a subtractor that subtracts the second analog signal from the delayed first analog signal and generates an output signal; and a controller that controls the digital filter based on a remaining interference component that is remaining in the output signal.

### CROSS-REFERENCE TO RELATED APPLICATIONS

This application claims priority from Japanese Patent Application No. 2008-050945 filed on Feb. 29, 2008, the entire contents of which are incorporated herein by reference.

### BACKGROUND OF THE INVENTION

1. Field of the Invention

An aspect of the present invention relates to a filter circuit that removes an interference component from a received signal, to a receiver using the filter circuit, and to a filtering method using the filter circuit.

2. Description of the Related Art

In a receiver of a radio communication system, a received signal obtained from an antenna which receives a radio signal is amplified by a low-noise amplifier. A received baseband signal is generated by downconverting the amplified signal at a frequency converter. A signal component of a desired band is extracted from the received baseband signal by, e.g., a lowpass filter. Then, the extracted signal is converted to a digital received signal by an analog-to-digital converter. Incidentally, a filter circuit for removing an interference component from the extracted signal can be provided at a preceding stage of the analog-to-digital converter.

The term “interference component” designates an unnecessary signal component which is included in a received signal outside the desired band. The interference component is assumed to be, e.g., a radio signal transmitted from another transmitter, a radio signal transmitted from a transceiver body on which the receiver is mounted, or unnecessary radiation from another integrated circuit (IC).

According to D. Cabric et al., “Novel Radio Architectures for UWB, 60 GHz, and Cognitive Wireless Systems”, EURASIP Journal on Wireless Communications and Networking, Vol. 2006, Article ID 17957, pp. 1-18., a filter circuit includes a first automatic gain control circuit, an analog-to-digital converter (ADC), a notch filter, an adaptive filter, a digital-to-analog converter (DAC), an analog delay element, a subtractor, and a second automatic gain control circuit. The aforementioned filter circuit branches an input signal into a first path consisting of the first automatic gain control circuit, the ADC, the notch filter, the adaptive filter, and the DAC, and a second path consisting of the analog delay element.

An input signal passing through the first path is controlled in signal amplitude by the first automatic gain control circuit. The input signal is converted to a digital signal by the ADC. An interference component is removed from the digital signal by the notch filter and the adaptive filter. The interference component is converted to an analog signal by the DAC. On the second path, the analog delay element provides a signal delay, which corresponds to a delay time caused due to the first path, to an input signal.

Signals respectively having passed through the first and second paths are input to the subtractor. The subtractor removes an interference component by subtracting the signal having passed through the first path from the signal having passed through the second path. The signal amplitude of a signal, from which the interference component is removed, is adjusted by the second automatic gain control circuit. Then, this signal is output to the ADC at the subsequent stage.

In the above-mentioned filter circuit, digital signal processing is performed on the first path. Thus, an error is difficult to be included in the frequency characteristic of the first path of the circuit. On the other hand, the second path includes the analog delay element. Thus, an error is included in the frequency characteristic of the second path of the circuit. The error of the frequency characteristic is changed according to parameters, such as temperature and processing conditions.

Thus, it is difficult to accurately match the frequency characteristic of the first path with that of the second path. Consequently, a deviation in the frequency characteristic is caused. When the frequency characteristics of both the paths are not accurately matched with each other, the subtractor cannot accurately remove an interference component.

### SUMMARY OF THE INVENTION

According to an aspect of the present invention, there is provided a filter circuit including: an analog-to-digital converter configured to convert a first analog signal into a first digital signal; a digital filter configured to extract an interference component from the first digital signal and to generate a second digital signal; a digital-to-analog converter configured to convert the second digital signal into a second analog signal; a delay circuit configured to delay the first analog signal based on a delay caused in the second analog signal and to generate a delayed first analog signal; a subtraction circuit configured to subtract the second analog signal from the delayed first analog signal and to generate an output signal; and a control circuit configured to control the digital filter based on a remaining interference component that is remaining in the output signal.

According to another aspect of the present invention, there is provided a receiver including the above-mentioned filter circuit.

According to still another aspect of the present invention, there is provided a filtering method operable in a filtering mode for removing an interference component from an input signal and in a correction mode for correcting a characteristic of a filter circuit, wherein, in the filtering mode, the filtering method includes: generating a first analog signal by sampling the input signal; generating a first digital signal by converting the first analog signal; generating a second digital signal by extracting the interference component from the first digital signal through a digital filter; generating a second analog signal by converting the second digital signal; generating a delayed first analog signal by delaying the first analog signal based on a delay caused in the second analog signal; and generating an output signal by subtracting the second analog signal from the delayed first analog signal, and wherein, in the correction mode, the filtering method includes: generating a standard signal that is a discrete time signal; converting the standard signal into a fourth digital signal; generating a delayed fourth digital signal by delaying the fourth digital signal by use of the digital filter; generating a fifth analog signal by converting the delayed fourth digital signal; generating a delayed fourth analog signal by delaying the fourth analog signal based on a delay in the fifth analog signal; and correcting a filter characteristic of the digital filter to reduce a difference between frequency responses of digital signals respectively obtained by analog-to-digital converting the delayed fourth analog signal and the fifth analog signal.

### BRIEF DESCRIPTION OF THE DRAWINGS

FIG. 1 is a diagram illustrating the configuration of a filter circuit 100 according to Embodiment 1 of the invention;

FIG. 2 is a diagram illustrating an example of a sampler 110 according to Embodiment 1;

FIGS. 3A and 3B are diagrams illustrating an example of a DAC 130 according to Embodiment 1;

FIGS. 4A and 4B are diagrams illustrating an example of a delay device 140 according to Embodiment 1;

FIGS. 5A and 5B are diagrams illustrating an example of a signal generator 170 according to Embodiment 1;

FIG. 6 is a flowchart illustrating an operation of a control circuit 180 according to Embodiment 1;

FIG. 7 is a diagram illustrating the configuration of a filter circuit 200 according to Embodiment 2 of the invention;

FIG. 8 is a flowchart illustrating a method of adjusting tap coefficients according to Embodiment 2;

FIG. 9 is a diagram illustrating the configuration of a filter circuit 300 according to Embodiment 3 of the invention;

FIG. 10 is a diagram illustrating the configuration of an analog filter 390 according to Embodiment 3;

FIG. 11 is a flowchart illustrating the configuration of the filter circuit 300 according to Embodiment 3; and

FIG. 12 is a diagram illustrating the configuration of a receiver according to Embodiment 4 of the invention.

### DETAILED DESCRIPTION OF THE INVENTION

Hereinafter, embodiments of the invention are described with reference to the accompanying drawings.

### Embodiment 1

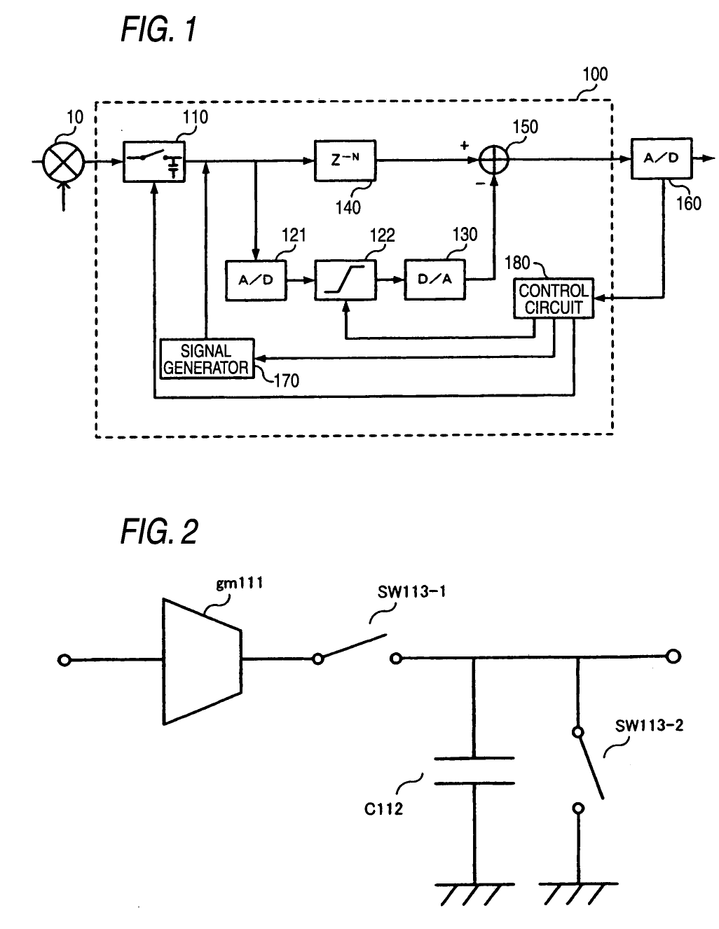

With reference to FIGS. 1 to 6, Embodiment 1 of the invention is described below. FIG. 1 is a diagram illustrating a filter circuit 100 according to Embodiment 1.

The filter circuit 100 removes an interference component included in a received signal that is downconverted by a frequency converter 10 at the preceding stage. A signal, from which the interference component is removed by the filter circuit 100, is converted into a digital signal by an analog-to-digital converter (ADC) 160. Then, the converted signal is demodulated by a digital processing portion (not shown).

The filter circuit 100 illustrated in FIG. 1 includes a sampler 110, an analog-to-digital converter (ADC) 121, a digital filter 122, a digital-to-analog converter (DAC) 130, a delay device 140, a subtractor 150, a signal generator 170, and a control circuit 180.

The frequency converter 10 provided at the preceding stage of the filter circuit 100 downconverts a signal received by an antenna (not shown) to generate a baseband signal. The baseband signal includes, in addition to a desired component, an interference component whose amplitude is larger than that of the desired component.

The sampler 110 performs sampling of a baseband signal (input signal) input from the frequency converter 10 at a given sampling frequency to time-discretize the baseband signal. Thus, the sampler 110 generates an analog discrete-time signal (first analog signal). The analog discrete-time signal output from the sampler 110 is branched into a first path, which includes the ADC 121, the digital filter 122, and the DAC 130, and a second path which includes the delay device 140.

The ADC 121 converts the analog discrete-time signal output from the sampler 110 into a digital signal (first digital signal), and then transfers the digital signal to the digital filter 122.

The digital filter 122 extracts an interference component outside the desired band from the digital signal output by the ADC 121 to generate a digital signal (second digital signal, hereunder referred to as an interference digital signal) that includes the interference component. The DAC 130 converts the interference digital signal generated at the digital filter 122 into an analog discrete-time signal (second analog signal).

Here, quantization noise in the frequency band of the desired component is generated by the digital filter 122 and the DAC 130. The bit resolution (the number of quantization bits) needed by the digital filter 122 and the DAC 130 is determined by a signal-to-noise ratio needed by whole system. Since, a dynamic range corresponding to 1 bit is about 6 dB, at least 1 bit is needed per 6 dB for a sum of ratio of a desired band signal to the other band signal in the input signal and a signal-to-noise ratio in the desired band.

The delay device 140 provides a signal delay, which is equal to a delay time caused in the first path (the ADC 121, the digital filter 122 and the DAC 130), to an analog discrete-time signal output from the sampler 110. Thus, the delay device 140 obtains the delayed analog discrete-time signal (the delayed first analog signal). A delay time caused in the first path is obtained as a discrete value that is a constant multiple of a clock cycle, because the ADC 121, the digital filter 122, and the DAC 130 are clock-controlled. Accordingly, the delay device 140 can grasp the delay time using a simple digital circuit, such as a counter for counting clock signals.

The subtractor 150 subtracts an analog discrete-time signal passing the first path from an analog discrete-time signal passing the second path, and passes a subtraction result to the ADC 160. While the analog discrete-time signal passing the second path includes both a desired component and an interference component, the analog discrete-time signal passing the first path includes mainly an interference component. Thus, the interference component can be removed by subtraction at the subtractor 150. A signal from the subtractor, in which the interference component is removed, is referred hereinafter to as a desired analog signal.

The signal generator 170 generates a standard discrete-time signal (fourth analog signal) in a correction mode operation which will be described below, and passes the generated signal to the ADC 121 and the delay device 140. Easily-generatable wide-band signals, such as an impulse signals and a step signal, are well suited to the standard discrete-time signals.

The control circuit 180 controls the sampler 110 and the signal generator 170, which will be described below, and switches the mode of the filter circuit 100 between the correction mode and a filtering mode (sampling mode). In the correction mode operation, the control circuit 180 compares a digital signal converted by the ADC 160 with a digital signal, into which a standard discrete-time signal is generated by the signal generator 170, to detect an error. Further, the control circuit 180 adjusts the characteristic of the digital filter 122 such that the detected error is equal to or less than a reference value.

Next, with reference to FIGS. 2 to 5B, an exemplary configuration of each component of the filter circuit 100 is described below. First, a charge sampler is described below as an example of the sampler 110 by referring to FIG. 2.

The charge sampler illustrated in FIG. 2 includes a transconductance amplifier gm111 for converting an input voltage into an electric current, a capacitor C112 for charge-sampling of an output current of the transconductance amplifier gm111, a switch SW113-1 for controlling the charge-sampling, and a switch SW113-2 for resetting the electric charge of the capacitor C112.

The switches SW113-1 and 113-2 operate complementarily with each other. When one of the switches SW113-1 and 113-2 is turned on, the other switch is turned off. During the switch SW113-1 is turned on, an output current of the transconductance amplifier gm111 is charge-sampled by the capacitor C112. During the switch 113-2 is turned on, the electric charge of the capacitor C112 is reset. Incidentally, the sampler 110 is not limited to the charge sampler illustrated in FIG. 2. For example, a voltage sampler can be used as the sampler 110.

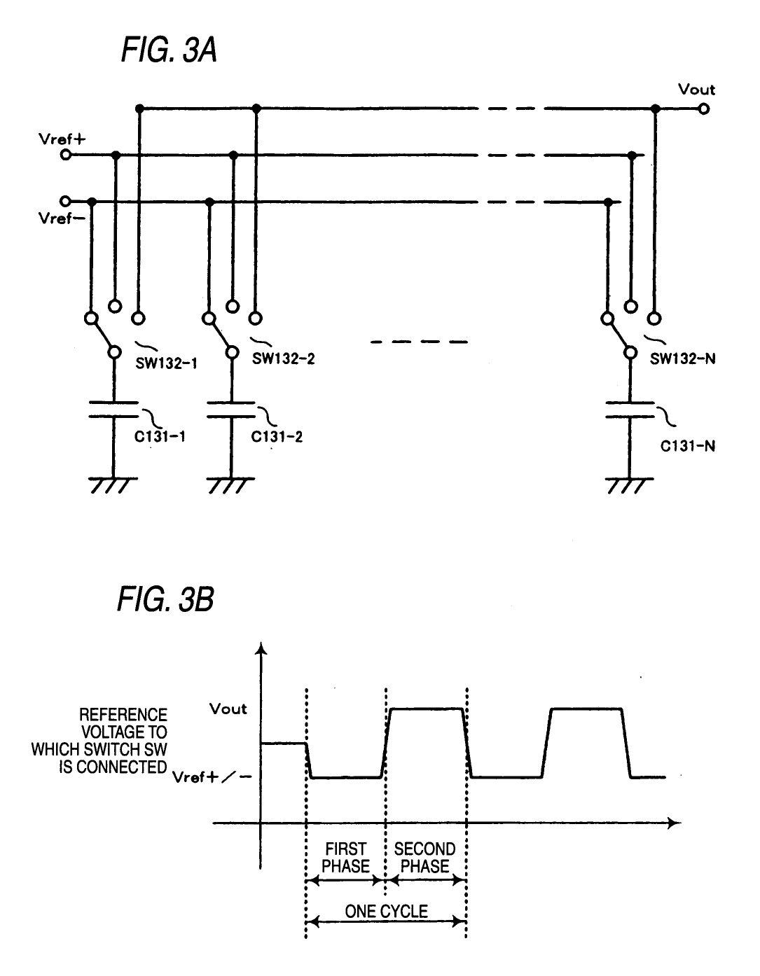

Hereinafter, an example of the ADC 130 is described with reference to FIGS. 3A and 3B. An N-bit resolution DAC 130 illustrated in FIG. 3A includes N capacitors C131-1 to 131-N and switches SW132-1 to 132-N each of which switches the connection of an associated one of the capacitors 131-1 to 131-N to among voltages.

The capacitors C131-1 to 131-N respectively correspond to the bits of data represented by a digital signal to be input to the DAC 130. That is, the capacitor C131-1 and the capacitor C131-N correspond to the least significant bit and the most significant bit, respectively. The capacitance of each of the capacitors C131-1 to 131-N is weighted by assigning a binary weight thereto. Thus, the capacitance of the capacitor C131-2 is twice that of the capacitor C131-1. The capacitance of the capacitor C131-N is 2^{N-1} times the capacitance of the capacitor C131-1.

Each of the switches SW132-1 and SW132-N repeats a switching operation by employing two phases as one cycle, as illustrated in FIG. 3B. In a phase 1, each of the switch SW132-1 to 132-N connects an associated one of the capacitors C131-1 to 131-N to a reference voltage Vref+ or Vref−.

Incidentally, in the phase 1, which of reference voltages Vref+ and Vref− each of the capacitors C131-1 to 131-N is connected to is determined according to which of a “high (H)” level and a “low (L)” level an output level of the digital filter 122 representing a bit corresponding to the associated capacitor is. In the phase 1, each of the capacitors C131-1 to C131-N stores electric charge corresponding to an associated digital input signal level. On the other hand, in the phase 2, each of the switches SW132-1 to 132-N connects an associated one of the capacitors C131-1 to C131-N to an output Qₒᵤₜ of the DAC 130. Then, a level corresponding to electric charge stored in each of the capacitors C131-1 to C131-N is superposed on the associated digital input signal level. Thus, a signal representing a resultant level corresponding to each of the capacitors is output therefrom as an analog discrete-time signal.

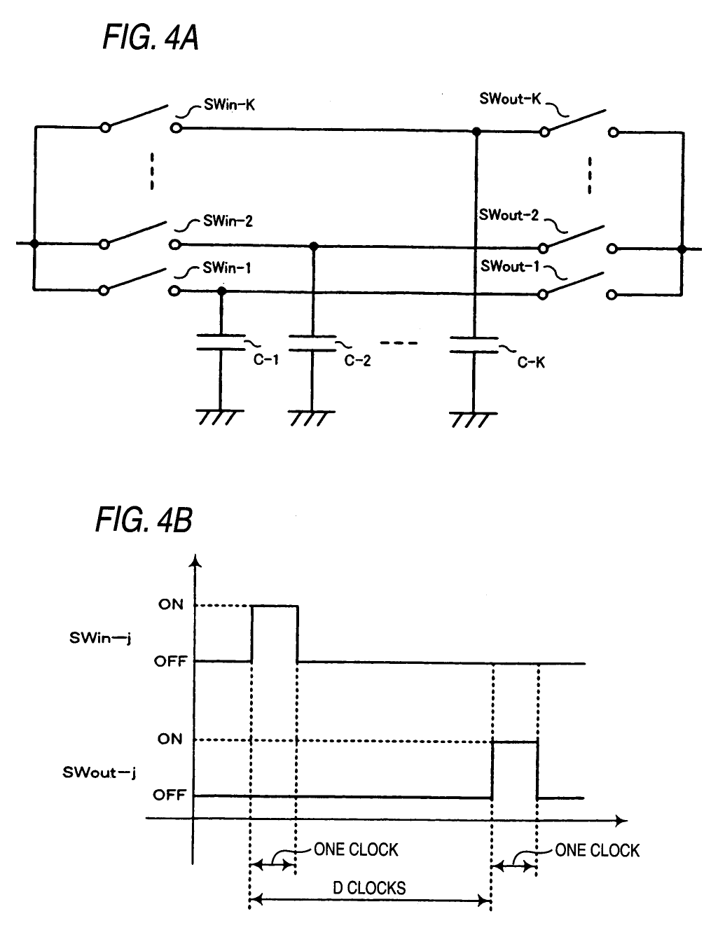

Hereinafter, an example of the delay device 140 is described with reference to FIGS. 4A and 4B.

The delay device illustrated in FIG. 4A is constructed by arranging K unit circuits, each of which includes two switches SWin and SWout and one capacitor C provided between the switches SWin and SWout, in parallel to one another (“K” is a given integer equal to or more than 2). The delay device illustrated in FIG. 4A can generate a signal delay that is a delay time of a given number of clock cycles, which ranges from one to (K−1).

An input signal is connected to one of the capacitors C-1 to C-K through the K switches SWin-1 to SWin-K. Thus, input electric charge is stored in the capacitor to which the input signal is connected. That is, the switches SWin-1 to SWin-K operate exclusively from one another. Thus, during one of the switches SWin-1 to SWin-K is turned on, all of the other switches are turned off. Incidentally, it is assumed that in an initial state, no electric charge is stored in all of the capacitors C-1 to C-K. Subsequently, input electric charges are sequentially and similarly stored in the capacitors in each of which electric charge is not stored.

Similarly, switches SWout-1 to SWout-K operate exclusively from one another. Input electric charge stored in an associated one of the capacitors is output therefrom after a given delay time is elapsed. For example, an operation of each of the switches SWin-j and SWout-j in the case where the delay time is set to D clock cycles, as illustrated in FIG. 4B, is described below.

First, the switch SWin-j is turned on. Thus, an input electric charge is stored in the capacitor C-j. Similarly, input electric charges are sequentially stored in the capacitors in which electric charge is not stored, until D-1 Clock cycles are elapsed. After D clock cycles are elapsed, the switch SWout-j is turned on, and the input electric charge stored in the capacitor C-j is taken out therefrom. Subsequently, the electric charge stored in the capacitor C-j is reset to “0”. Similarly, the input electric charge stored in each of the other capacitors is taken out therefrom after D clock cycles are elapsed since the input electric charge has been stored therein. In addition, the electric charge stored in each of the other capacitors is reset to “0”. Input electric charge, which is input to the delay device during the other input electric charge is taken out, is stored in one of the other (N-D) capacitors in each of which electric charge stored therein is “0”.

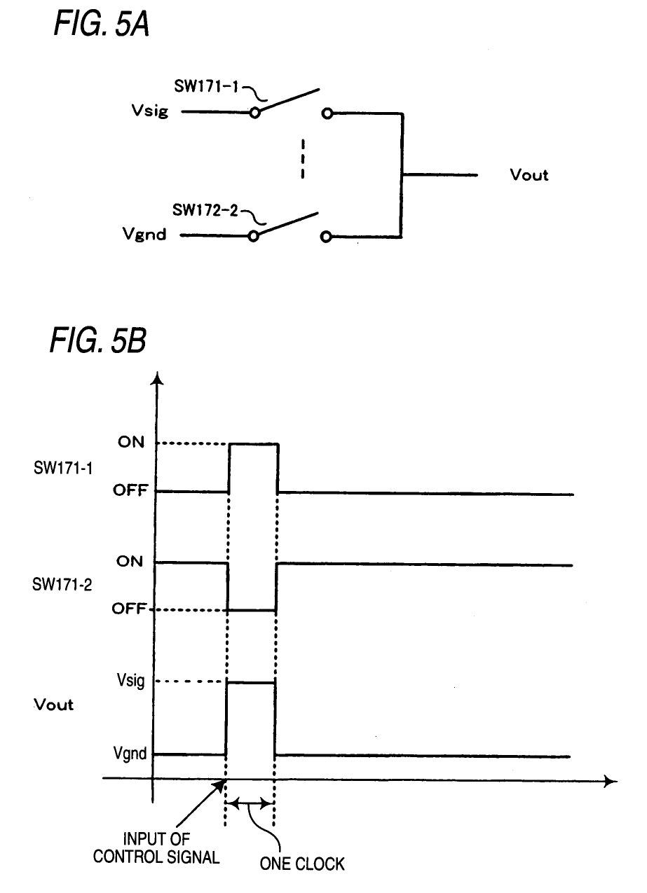

Hereinafter, an example of the signal generator 170 is described below with reference to FIGS. 5A and 5B. The signal generator 170 illustrated in FIGS. 5A and 5B outputs an impulse signal as the standard discrete-time signal.

The signal generator 170 illustrated in FIG. 5A has two direct-current voltage terminals V_{gnd} and V_{sig} respectively connected to a reference voltage and a signal voltage, an output terminal Vₒᵤₜ, a switch SW171-1 connected between the direct-current voltage terminal V_{sig} and the output terminal Vₒᵤₜ and a switch SW171-2 connected between the direct-current voltage terminal V_{gnd} and the output terminal Vₒᵤₜ.

The signal generator 170 illustrated in FIGS. 5A and 5B generates, when a control signal is input from the control circuit 180 thereto, an impulse signal as follows.

The output terminal Vₒᵤₜ is connected to one of the direct-current voltage terminals V_{gnd} and V_{sig} via an associated one of the switches SW171-1 and SW171-2. That is, the switches SW171-1 and SW171-2 operate complementarily from each other. Thus, when one of the switches SW171-1 and SW171-2 is turned on, the other of the switches SW171-1 and SW171-2 is turned off. For example, when a control signal is input thereto from the control circuit 180 to generate an impulse signal, as illustrated in FIG. 5B, the switch SW171-1 is turned on, while the switch SW171-2 is turned off. Thus, the direct-current voltage terminal V_{sig} is connected to the output terminal Vₒᵤₜ. After one clock cycle is elapsed since the input of the control signal thereto, the switch SW171-1 is turned off this time, while the switch SW171-2 is turned on. Thus, the voltage terminal V_{gnd} is connected to the output terminal Vₒᵤₜ. The signal generator 170 generates an impulse signal by this operation.

Although the signal generator for generating an impulse signal has been described, an arbitrary signal can be applied as the standard discrete-time signal. Easily-generatable wide-band signal may be suited to simple and accurate correction. In addition to the aforementioned impulse signal, for example, a step signal may be used.

Next, an operation of the filter circuit 100 according to the present embodiment is described with reference to FIG. 1. The filter circuit 100 operates in two modes, i.e., a correction mode and a filtering mode. In the correction mode, an error of the frequency characteristic caused in an analog portion to be described below is detected to correct the frequency characteristic of the digital filter 122. In the filtering mode, a received signal including an interference component is processed.

First, an operation of the filter circuit 100 in the filtering mode is described below with reference to FIG. 1.

The control circuit 180 outputs control signals to the sampler 110 and the signal generator 170. When receiving the control signal, the signal generator 170 halts an operation, i.e., the signal generator 170 does not pass the standard discrete-time signal to the ADC 121 and the delay device 140 at the subsequent stage. Further, the sampler 110 performs the sampling and the time-discretization of a baseband signal received from the frequency converter 10 at a given sampling frequency.

The analog discrete-time signal sampled by the sampler 110 is branched into the first path and the second path. First, the baseband signal branched (input) to the first path is input to the ADC 121 and is converted into a digital signal. Next, this digital signal is input to the digital filter 122.

In the digital filter 122, a signal component of a desired band is removed from the digital signal. Thus, a signal component (interference component) outside the desired band is extracted to generate an interference digital signal. The interference digital signal is input to the DAC 130 and is converted into an analog signal (interference analog signal). The subtractor 150 performs the subtraction between the interference digital signal and the analog discrete-time signal that is passed through the second path.

On the other hand, the analog discrete-time signal branched into the second path is input to the delay device 140. The analog discrete-time signal is input to the subtractor 150 after the delay device 140 provides a signal delay, which is equal to a delay time caused by the ADC 121, the digital filter 122, and the DAC 130, to the analog discrete-time signal.

The subtractor 150 subtracts the interference analog signal, which is passed through the first path, from the analog discrete-time signal passed through the second path. A desired analog signal is output to the ADC 160 from the subtractor 150.

The desired analog signal is converted into a desired digital signal at the ADC 160 and is output to the digital signal processing portion (not shown).

Next, the correction mode operation of the filter circuit 100 is described below. This operation is similar to the filtering mode operation except that the standard discrete-time signals generated by the signal generator 170 are input to the first path and the second path, and that the control circuit 180 detects an error of the frequency characteristics of the first path and the second path. Therefore, a redundant description of the operation is omitted.

Each of the sampler 110, the ADCs 121 and 160, the delay device 140, and the subtractor 150 includes an analog circuit using analog devices, such as a switch and a capacitor. An analog circuit is also used in a connecting portion between such analog circuit and another device. In the description of the present embodiment, elements including analog circuits are referred to as an analog portion. Such an analog circuit causes an error between a desired frequency characteristic and an actual frequency characteristic due to parasitic elements and to process variation.

The closer the frequency characteristic of the constituent element included in the first path and that of the constituent element included in the second path are to each other, the more accurately the filter circuit 100 removes an interference component from a received signal. However, since the filter circuit 100 includes an analog portion, the frequency characteristics of the two paths do not become the same, thereby deteriorating a removing accuracy of an interference component from a received signal.

Ideally, the magnitude of the remaining interference component, which is not removed from the received signal, depends upon the quantization noise of the DAC 130 and is limited to a certain value. However, when an error between the frequency characteristics of the first and second paths is larger than the quantization noise of the DAC 130, the magnitude of the remaining interference component depends upon the error of the frequency characteristic. Accordingly, it is important for accurately removing the interference component from the received signal to reduce an error between the frequency characteristics of the two paths.

Thus, the filter circuit 100 has the correction mode in addition to the filtering mode. In the correction mode, the filter circuit 100 operates to reduce an error between the frequency characteristics of the two paths. More specifically, the control circuit 180 compares a desired digital signal output by the ADC 160 with a digital signal obtained by converting the standard discrete-time signal and detects a signal difference therebetween. Consequently, the control circuit 180 detects an error between the frequency characteristics of the first and second paths. The control circuit 180 compares the detected signal error with a reference value. The control circuit 180 reduces the error between the frequency characteristics of the first and second paths by adjusting the characteristic of the digital filter 122 such that the detected signal error is equal to or less than the reference value.

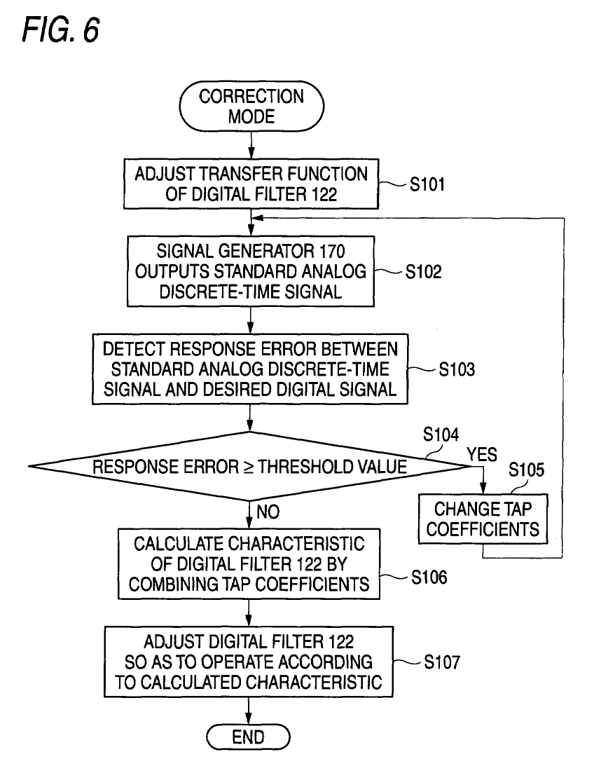

Hereinafter, the correction mode operation of the control circuit 180 is described with reference to a flowchart illustrated in FIG. 6. It is assumed herein that the digital filter 122 is a digital finite impulse response (FIR) filter, and that the tap coefficients thereof can be changed according to a control signal output from the control circuit 180.

First, in step S101, the control circuit 180 adjusts the transfer function of the digital filter 122 such that the delay time of the first path is equal to the delay time of the second path, i.e., that the digital filter 122 is functioning as an ideal delay device having no frequency characteristic. Next, in step S102, the control circuit 180 outputs a control signal to the signal generator 170 so that the signal generator 170 outputs a standard discrete-time signal.

When the signal generator 170 outputs the standard discrete-time signal, processing similar performed in the filtering mode operation is performed in each portion. Thus, a desired digital signal output from the ADC 160 is input to the control circuit 180. In step S103, the control circuit 180 compares the desired digital signal with a signal obtained from the standard discrete-time signal to detect an error of the frequency response to the standard discrete-time signal.

In step S104, the control circuit 180 compares the detected response error with a threshold value TH. If the error is equal to or more than the threshold value TH, the characteristic (tap coefficients) of the digital filter 122 is changed in step S105. Then, the control circuit 180 returns to step S102.

The control circuit 180 selects at least one variable of the tap coefficients and increases or decreases the selected variable.

On the other hand, when the error is less than the threshold value TH, in step S106, the tap coefficients of the digital filter 122 determined in processes up to step S105 is combined with the tap coefficients corresponding to the filter characteristic for extracting a component outside a desired band. Thus, the characteristic of the digital filter 122 is calculated.

Finally, in step S107, the control circuit 180 adjusts the tap coefficients of the digital filter 122 to cause the digital filter 122 to operate according to the characteristic calculated in step S106.

In the correction mode, first, the control circuit 180 calculates initial tap coefficients of the digital filter 122 to be functioning as an ideal delay device having no frequency characteristic. Next, the control circuit 180 optimizes the initial tap coefficients to optimum tap coefficients through the above-mentioned steps.

The correction operation for the analog portion may be automatically performed at a given period. After the characteristic of the digital filter 122 is set in the correction mode, the mode is changed to the filtering mode from the correction mode. When the frequency characteristic of the analog portion is mainly depends on a capacity ratio or the like and is less subjected to the external environment variation, such as the temperature variation, the correction operation of the digital filter 122 may be performed once before shipping. When the correction operation is performed only once before shipping, the filter circuit 100 can be constructed such that the signal generator 170 and the control circuit 180 are provided externally, and that the signal generator 170 and the control circuit 180 are detached therefrom after the correction operation.

When the frequency characteristic of the analog portion depends on the external environment, such as temperature, the correction mode operation may be performed repeatedly, e.g., at the start-up of the receiver, the start of communication, and the elapse of a given time period. For example, when the analog portion includes a charge sampling circuit, the frequency characteristic of the transconductance amplifier may be corrected.

Thus, the tap coefficients of the digital filter 122 can be optimized by operating the filter circuit 100 in the correction mode. Consequently, an interference component can be removed from a received signal with high precision. This can reduce the consumption current of the ADC 160. Hereinafter, the reasons for being able to reduce the consumption current of the ADC 160 are described.

A radio signal includes a desired component and an interference component. Generally, in a radio communication system, the interference component has a signal amplitude higher than that of the desired component by several ten dB. A resolution (the number of input bits) of the ADC 160 is set so that the desired component is distinguishable from the interference component. As the signal amplitude of the interference component increases, the resolution required to the ADC 160 increases. The number N of input bits required to the ADC 160 is approximately given by:

N=(L/6)+M

where L is a ratio in voltage magnitude (dB) between the desired component and the (remaining) interference component, and M is the number of bits to receive the desired component.

On the other hand, generally, the consumption current of the ADC 160 increases in proportion to 2^{N} (incidentally, N is the number of input bits).

As described above, a received signal includes an interference component that is larger in signal amplitude than a desired component. Accordingly, it is necessary for the analog-to-digital conversion of the received signal to increase the number N of input bits of the ADC 160. Consequently, the consumption current thereof increases.

However, the filter circuit 100 according to the present embodiment can remove an interference component from a received signal with high accuracy. Thus, the number of bits of the ADC 160 should be sufficient to enable the conversion of the signal amplitude of the desired component (about M bits). As compared with the case that the received signal includes the interference component, the consumption current can be reduced.

As described above, according to Embodiment 1, the tap coefficients of the digital filter 122 are optimized by operating the filter circuit 100 in the correction mode. Consequently, the filter circuit 100 according to Embodiment 1 can remove the interference component from the received signal with high precision.

Further, it is preferable for setting better filter coefficients in the correction mode that an error between the delay time of the first path and the processing delay time of the second path is small. Thus, according to the present embodiment, a signal is branched into the first path and the second path after a baseband signal is converted into an analog discrete-time signal using the sampler 110. Consequently, the delay time of the first path can be adjusted to that of second path using a simple digital circuit. Furthermore, both of the first path and the second path are signal paths through which signals time-discretized at a synchronous clock frequency are passed. Thus, the delay times of the paths can be adjusted to each other with high accuracy. Since the present embodiment can remove an interference component from a received signal with high precision, the consumption current of the ADC 160 can be reduced. Further, since the filter circuit according to the present embodiment is less affected by the aliasing of the frequency, the configuration of a comparison circuit (not shown) in the control circuit 180 can be simplified. Consequently, a comparison time can be reduced.

### Embodiment 2

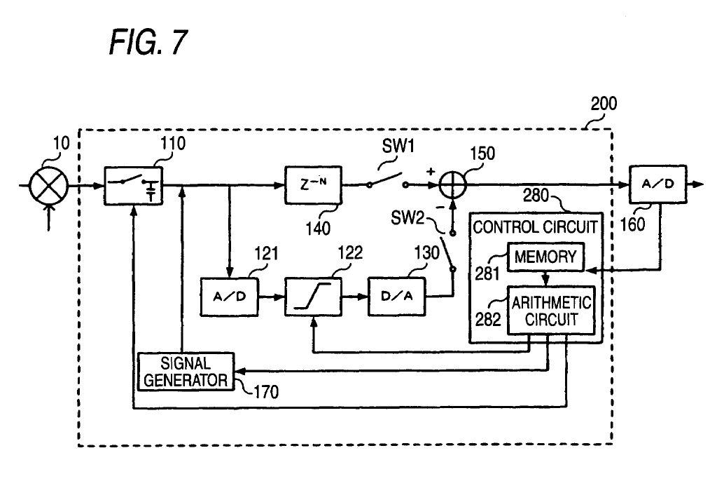

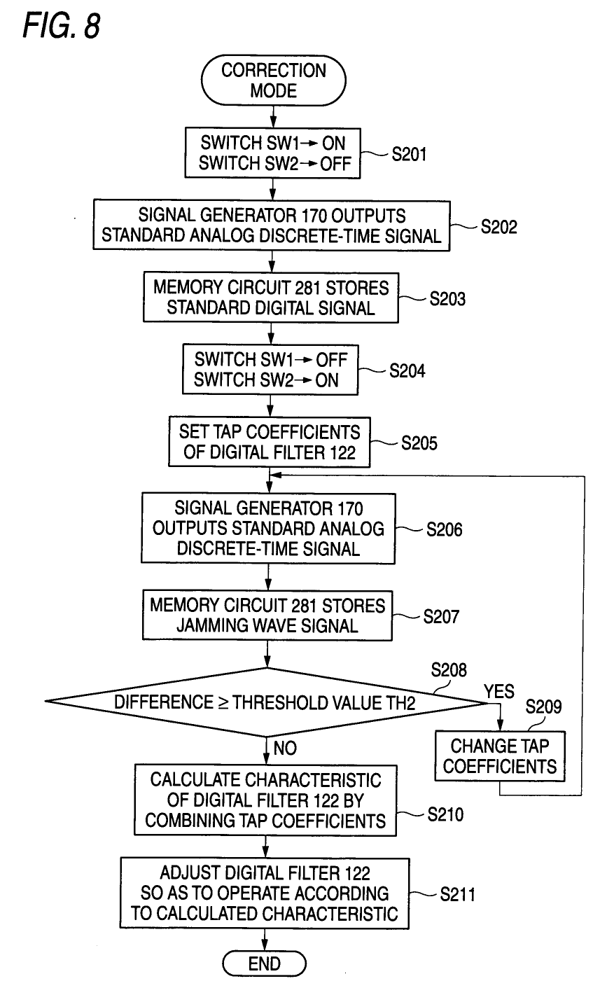

Next, Embodiment 2 of the invention is described below with reference to FIGS. 7 and 8. A filter circuit 200 illustrated in FIG. 7 has the same configuration as that of the filter circuit 100 illustrated in FIG. 1 with the excepts that a control circuit 280 includes a memory circuit 281 and an arithmetic circuit 282, that the filter circuit 200 includes also a switch SW1 provided between a delay device 140 and a subtractor 150, and that the filter circuit 200 includes also a switch SW2 provided between a DAC 130 and the subtractor 150. Therefore, constituent elements of Embodiment 2, which are the same as those of Embodiment 1, are designated with the same reference numeral as used to designate the same constituent elements of Embodiment 1. Thus, the description of such constituent elements of Embodiment 2 is omitted. According to Embodiment 2, the tap coefficients of a digital filter 122 can be adjusted in a smaller number of steps.

The memory circuit 281 is connected to an ADC 160. The memory circuit 281 stores signals (standard digital signals) obtained by the digital conversion of a signal (interference signal), which is passed through the first path and includes an interference component, and a standard signal passed through the second path.

The arithmetic circuit 282 compares an interference signal stored in the memory circuit 281 with the standard digital signal and calculates an error between the two signals. And, the arithmetic circuit 282 changes the tap coefficients of the digital filter 122 to reduce the calculated error.

The switches SW1 and SW2 are controlled by the control circuit 280. The switches SW1 and SW2 complementarily operate in the correction mode. When one of the switches SW1 and SW2 is turned on, the other switch is turned off. Further, in the filtering mode, both the switches SW1 and SW2 are turned on. When the switch SW1 is turned on and the switch SW2 is turned off, the memory circuit 281 stores the standard digital signal. When the switch SW1 is turned off and the switch SW2 is turned on, the memory circuit 281 stores an interference signal.

Next, a specific method for adjusting the tap coefficients in the correction mode is described with reference to a flowchart illustrated in FIG. 8. This flowchart describes an exemplary operation performed in steps S102 to S107 illustrated in FIG. 6 in detail. The other operations of the filter circuit 200 are similar to those of the filter circuit 100 illustrated in FIG. 1. Thus, the description of such operations of the filter circuit 200 is omitted.

First, in step S201, the control circuit 280 turns on the switch SW1 and turns off the switch SW2. Next, in step S202, the control circuit 280 instructs a signal generator 170 to generate a standard discrete-time signal.

In step S203, the standard discrete-time signal generated by the signal generator 170 is converted into a digital signal (standard digital signal) at the ADC 160 after the delay device 140 provides a given delay time to the standard discrete-time signal. The digital signal is stored in the memory circuit 281.

Next, in step S204, the control circuit 280 turns off the switch SW1 and turns on the switch SW2.

In step S205, the control circuit 280 sets the tap coefficients of the digital filter 122 such that the digital filter 122 has the same delay amount as that thereof in the filtering mode. That is, the control circuit 280 sets the tap coefficients so that the filter 122 serves as an ideal delay device. Consequently, the digital filter 122 operates as an ideal delay device having no frequency characteristic.

Next, in step S206, the control circuit 280 gives an instruction to the signal generator 170 such that the signal generator 170 generates a standard discrete-time signal.

The standard discrete-time signal generated by the signal generator 170 passes through the second path and becomes a signal including an interference component. This signal is stored in the memory circuit 281. That is, the standard discrete-time signal is converted at the ADC 121 into a digital signal. The digital signal passes through the digital filter 122. Then, the digital signal is converted at the DAC 130 into an analog signal. Subsequently, this analog signal is converted at the ADC 140 into a digital signal (interference signal). In step S207, this digital signal is stored in the memory circuit 281. In the correction mode, the digital filter 122 operates as an ideal delay device and does not extract an interference component. Instead, the digital filter 122 provides a delay time, which is equal to the delay time of the delay device 140, to the digital signal.

In step S208, the arithmetic circuit 282 calculates a difference in frequency response between the interference signal stored in the memory circuit 281 and the standard digital signal. Then, the arithmetic circuit 282 compares the calculated difference with a threshold value TH2.

If the calculated difference is equal to or more than the threshold value TH2 (YES in step S208), in step S209, the tap coefficients are calculated and adjusted as follows. Then the control circuit 280 returns to step S206.

That is, instep S209, first, discrete Fourier transforms are performed on the frequency responses of the interference signal and the standard digital signal, which are calculated in step S208. Subsequently, a result of the discrete Fourier transform performed on the interference signal is divided by a result of the discrete Fourier transform performed on the standard digital signal. A result of this division is a frequency characteristic needed by the digital filter 122 in order to equalize the frequency characteristics of the two paths. The tap coefficients of the digital filter 122 can be obtained by performing an inverse Fourier transform on the result of the division. For accurately calculating the tap coefficients, the wide-band signals (e.g., impulse signals) are preferable.

On the other hand, if the difference calculated in step S208 is equal to or less than the threshold value TH2 (NO in step S208), in step S210, the control circuit 280 combines the tap coefficients set in the digital filter 122 with tap coefficients needed for extracting the interference component. In step S211, the control circuit 280 newly sets the resultant tap coefficients as those of the digital filter 122. Then, processing is finished.

As described above, according to Embodiment 2, advantages similar to those of Embodiment 1 can be obtained. In addition, because the tap coefficients are calculated using the frequency response of the interference signal passing through the first path and that of the standard digital signal passing through the second path, instead of individually adjusting a plurality of variables included in the tap coefficients, a plurality of variables can be adjusted at one time. Thus, the number of necessary steps for calculating the tap coefficients can be reduced. In addition, the tap coefficients can be calculated by performing simple operations, such as a Fourier transform of each frequency response and a division. Thus, the control circuit 280 can simply be constructed.

According to the present embodiment, the switch SW1 is provided between the delay device 140 and the subtractor 150, while the switch SW2 is provided between the DAC 130 and the subtractor 150. However, the number and the arrangement of switches can be optional in the case of storing results, which are obtained using the standard discrete-time signals passing through the first and second paths, in the memory circuit 281. For example, signals can selectively be distributed to the paths by providing a switch at a branch point between the two paths. In this case, the number of a switch is 1. Alternatively, the control circuit 280 can control each portion, through which no signals should pass, so as not to operate. In this case, no switches are necessary.

Although, in step S205 illustrated in FIG. 8, the initial tap coefficients of the digital filter 122 are given so as to be functioning as an ideal delay device, the initial tap coefficients may be given based on an expected error between the frequency characteristics of the first and second paths. By giving the expected error as the initial tap coefficients, the desired tap coefficients can be derived in a smaller number of steps.

### Embodiment 3

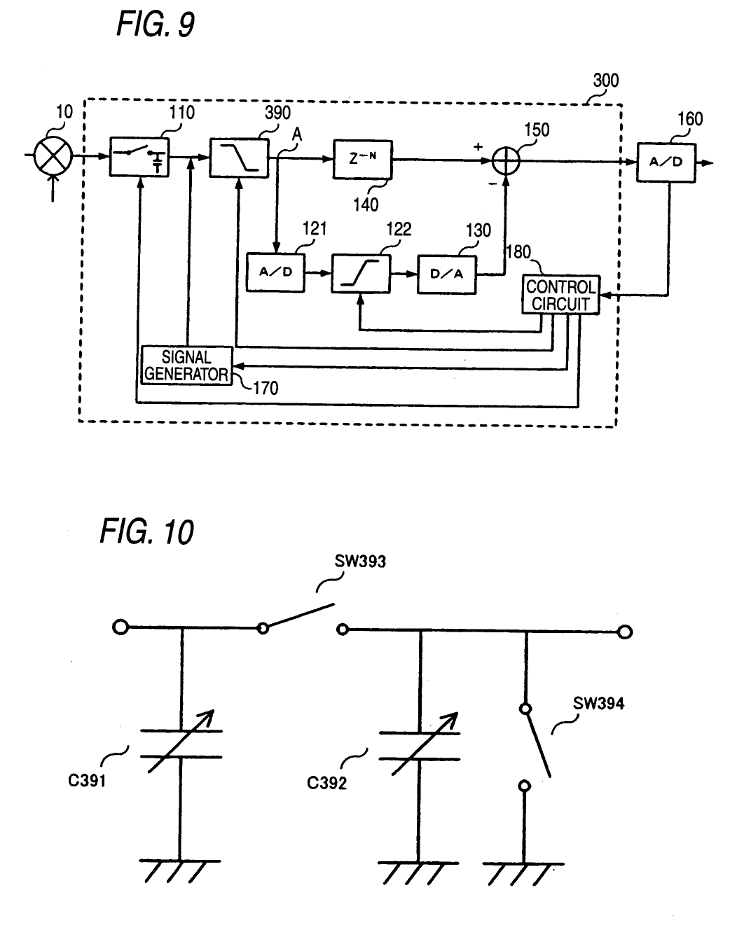

Next, Embodiment 3 of the invention is described hereinafter with reference to FIGS. 9 to 11. A filter circuit 300 illustrated in FIG. 9 has the same configuration as that of the filter circuit 100 illustrated in FIG. 1 with the except that the filter circuit 300 illustrated in FIG. 9 further includes an analog filter 390. Thus, constituent elements of Embodiment 3, which are the same as those of Embodiment 1, are designated with the same reference numerals as used to designate the same constituent elements of Embodiment 1. Thus, the description of such constituent elements of Embodiment 3 is omitted.

The analog filter 390 is provided between the sampler 110 and a branch point A which is provided between the first and second paths. The analog filter 390 attenuates a signal outside a desired band from a discrete-time signal output by the sampler 110 or from a standard discrete-time signal generated by a signal generator 170.

Hereinafter, an example of the analog filter 390 is described with reference to FIG. 10. The analog filter 390 illustrated in FIG. 10 includes a history capacitor 391, a rotating capacitor 392, a switch SW393, and a reset switch SW394.

When a discrete signal is input to the analog filter 390, first, the signal is charged into the history capacitor 391. Subsequently, the switch SW393 is turned on. In addition, the reset switch SW394 is turned off. A part of electric charge charged into the history capacitor 391 is moved to the rotating capacitor 392. After a given time is elapsed, the switch SW393 is turned off. Then, a signal is read from the rotating capacitor 392. Subsequently, the reset switch SW394 is turned on. The electric charge stored in the rotating capacitor 392 is discharged.

Subsequently, a discrete signal is charged into the history capacitor 391. Incidentally, the history capacitor 391 is such that electric charge stored therein is not discharged therefrom, differently from the rotating capacitor 392. Thus, electric charge, whose amount corresponds to a sum of the discrete signal stored in the history capacitor 391 the last time and the discrete signal stored therein this time, is stored therein. Next, the switch SW393 is turned on, while the switch SW394 is turned off. Then,apart of the electric charge charged into the history capacitor 391 is moved to the rotating capacitor 392. After a given time is elapsed, the switch SW393 is turned off. Then, a signal is read from the rotating capacitor 392. Subsequently, the reset switch SW394 is turned on. The electric charge stored in the rotating capacitor 392 is discharged.

The analog filter 390 attenuates a signal outside the desired band from the input signal by repeating this operation. The filter characteristic of the analog filter 390 is determined by the capacity ratio between the history capacitor 391 and the rotating capacitor 392. Thus, the filter characteristic can be adjusted by variably setting the capacity ratio between the history capacitor 391 and the rotating capacitor 392.

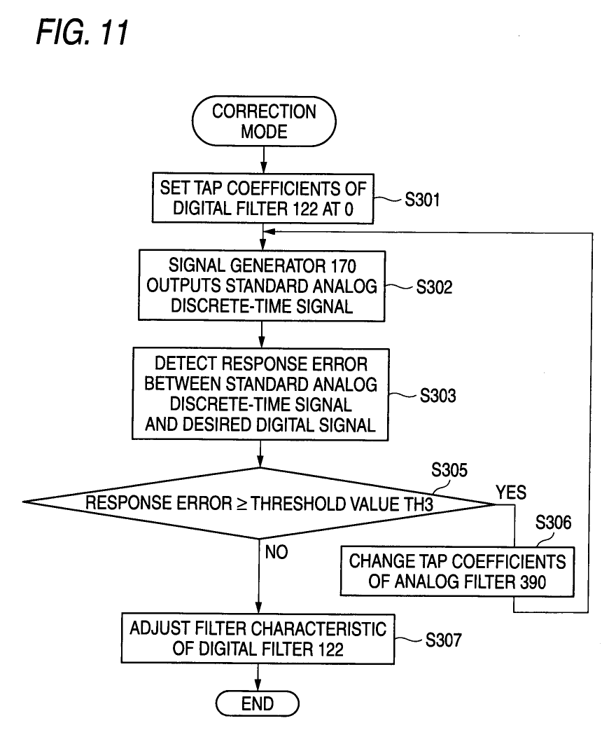

Next, an operation of the filter circuit 300 according to the present embodiment is described below with reference to FIG. 11. The filter circuit 300 has a filtering mode in which a received signal including an interference component is processed, and a correction mode in which the filter characteristics of the analog filter 390 and the digital filter 122 are corrected.

In the filtering mode, the filter circuit 300 operates similarly to the filter circuit 100 illustrated in FIG. 1 with the except that an analog discrete-time signal output from the sampler 110 is input to the ADC 121 and the delay device 140 after a signal outside the desired band is attenuated by the analog filter 390.

An operation in the correction mode of the filter circuit 300 is described below. The filter circuit 300 adjusts the filter characteristic (tap coefficients) of the digital filter 122 after the filter characteristic of the analog filter 390 is first adjusted.

First, in step S301, the control circuit 180 sets the tap coefficients of the digital filter 122 at 0. Next, in step S302, the control circuit 180 outputs a control signal to the signal generator 170 in order to cause the signal generator 170 to output a standard discrete-time signal.

When the signal generator 170 outputs a standard discrete-time signal, processing similar to that to be performed in the filtering mode is performed at each portion. Thus, a desired digital signal output from the ADC 160 is input to the control circuit 180. In step S303, the control circuit 180 compares the desired digital signal with a signal obtained by performing the digital conversion of the standard discrete-time signal. Thus, the control circuit 180 detects an error of the frequency response corresponding to the standard discrete-time signal.

Then, in step S304, the control circuit 180 compares the error of the response detected in step S303 with a threshold value TH3. If the error is equal to or more than the threshold value TH3, the control circuit 180 changes the filter characteristic (e.g., the capacity ratio between the history capacity 391 and the rotating capacitor 392 in the case of the example illustrated in FIG. 10) of the analog filter 390 in step S305. Then, the control circuit 180 returns to step S302.

On the other hand, if the error is less than the threshold value TH3, the control circuit 180 calculates and sets the filter characteristic of the analog filter 390 in step S306 by combining the filter characteristic of the analog filter 390, which is determined in processes up to step S305, with a filter characteristic for attenuating the component outside the desired band.

Subsequently, the control circuit 180 performs the adjustment of the filter characteristic of the digital filter 122 in step S307. A method of adjusting the filter characteristic of the digital filter 122 is the same as that of adjusting the filter characteristic of the filter circuit 100 illustrated in FIG. 1. Thus, the description of such a method is omitted.

As described above, according to Embodiment 3, advantages similar to those of Embodiment 1 can be obtained. In addition, the dynamic range of the ADC 121 can be reduced by providing the analog filter 390 in the filter circuit and by attenuating a signal outside the desired band of a signal to be input to the ADC 121. Moreover, even when the frequency of the input signal and the level of the interference component largely change, change in the dynamic range of the ADC 121 can be suppressed by adjusting the filter characteristic of the analog filter 390 before the filter characteristic of the digital filter 122 is adjusted. Thus, the design of the ADC 121 is facilitated. Furthermore, reduction in the power consumption and the circuit area of the filter circuit can be achieved.

Incidentally, although the analog filter 390 is provided in the filter circuit 100 illustrated in FIG. 1 according to Embodiment 3, the analog filter 390 can be provided in the filter circuit 200 illustrated in FIG. 7.

### Embodiment 4

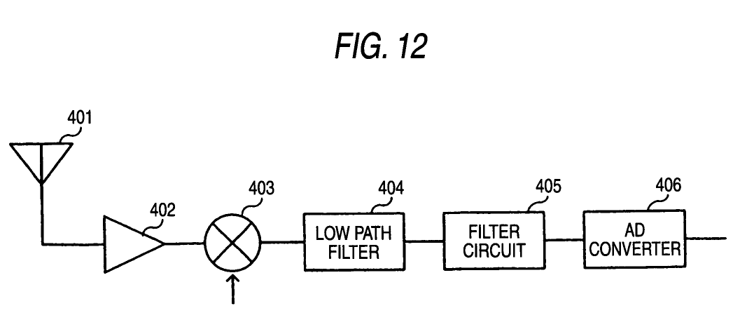

A receiver according to Embodiment 4 is described with reference to FIG. 12. The receiver illustrated in FIG. 12 includes an antenna 401, a low-noise amplifier 402, a frequency converter 403, a filter 404, a filter circuit 405, and an analog-to-digital converter (ADC) 406.

A signal received by the antenna 401 is amplified at the low-noise amplifier 402. Then, the amplified signal is downconverted at the frequency converter 403. The filter 404 is a lowpass filter and removes a high-frequency interference component included in a received baseband signal that is generated by the frequency converter 403.

The filter circuit 405 is constructed according to one of the aforementioned Embodiments 1 to 3. The filter circuit 405 further removes an interference component from the received baseband signal from which the high-frequency interference component has been removed at the filter 404. An output signal of the filter circuit 405 is converted at the ADC 406 into a digital signal. The digital signal is demodulated at a digital signal processing portion (not shown).

As described above, according to Embodiment 4, the filter circuit according to one of Embodiments 1 to 3 is provided between the filter 14 and the ADC. Consequently, the receiver according to the present embodiment can enhance the precision of removing an interference component. In addition, in the receiver according to the present embodiment, the electric power consumption can be reduced since the ADC 406 is constructed with lower bit resolution.

Although an output of the ADC 160 provided at the subsequent stage of the filter circuit according to each of Embodiments 1 to 4 is input to the control circuit 180, the ADC 160 can be provided in the filter circuit. In this case, the ADC can be omitted by adapting the filter circuit such that an output of the analog-to-digital circuit included in the filter circuit is input to a digital signal processing portion (not shown).

The invention is not limited to the aforementioned embodiments as they are. The invention can be embodied by changing components thereof without departing from the gist thereof in an implementation stage. Further, various modifications of the invention can be made by appropriately combining a plurality of components disclosed in the foregoing description of the embodiments. For example, several components can be deleted from all the components described in the embodiment. Moreover, components of different embodiments can appropriately be combined with one another.

According to an aspect of the invention, there is provided a filter circuit enabled to remove an interference component with high accuracy, a receiver using this filter circuit, and a filtering method using this filter circuit.

What is claimed is:

1. A filter circuit comprising:
an analog-to-digital converter configured to convert a first analog signal into a first digital signal;
a digital filter configured to extract an interference component from the first digital signal and to generate a second digital signal;
a digital-to-analog converter configured to convert the second digital signal into a second analog signal;
a delay circuit configured to delay the first analog signal based on a delay caused in the second analog signal and to generate a delayed first analog signal;
a subtraction circuit configured to subtract the second analog signal from the delayed first analog signal and to generate an output signal; and
a control circuit configured to control the digital filter based on a remaining interference component that is remaining in the output signal.

2. The filter circuit of claim 1 further comprising:
a signal generation circuit configured to generate a standard signal as the first analog signal,
wherein the control circuit:
controls the signal generation circuit to generate the standard signal; and
adjusts a filter characteristic of the digital filter so that a difference between frequency responses of the output signal and the standard signal is reduced.

3. The filter circuit of claim 1,
wherein the control circuit:
converts the delayed first analog signal into a third digital signal;
converts the second analog signal into a fourth digital signal; and
adjusts a filter characteristic of the digital filter so that a difference between frequency responses of the third digital signal and the fourth digital signal is equal to or less than a given value.

4. The filter circuit of claim 1,
wherein the control circuit:
converts the delayed first analog signal into a third digital signal;
converts the second analog signal into a fourth digital signal;
acquires frequency responses of the third digital signal and of the fourth digital signal;
acquires Fourier-transformed frequency responses by performing a Fourier transformation on each of the frequency responses;
subtracts the Fourier-transformed frequency response of the fourth digital signal from the Fourier-transformed frequency response of the third digital signal;
performs an inverse Fourier transformation on a subtracted result of the Fourier-transformed frequency responses; and
sets a inverse-Fourier-transformed result as filter coefficients of the digital filter.

5. The filter circuit of claim 2,
wherein the standard signal includes:
an impulse signal; or
a step signal.

6. The filter circuit of claim 2,
wherein, when the difference between the frequency responses is equal to or larger than a threshold value, the control circuit changes a filter coefficient of the digital filter.

7. The filter circuit of claim 1 further comprising:
an analog filter configured to attenuate the interference component included in the first analog signal.

8. The filter circuit of claim 7,
wherein the control circuit adjusts a filter characteristic of the digital filter after adjusting a filter characteristic of the analog filter.

9. The filter circuit of claim 1 further comprising:
a sampling circuit configured to generate the first analog signal by sampling an input signal, and to provide the first analog signal to the analog-to-digital converter and the delay circuit.

10. A receiver comprising the filter circuit of claim 1.

11. A filtering method operable in a filtering mode for removing an interference component from an input signal and in a correction mode for correcting a characteristic of a filter circuit,
wherein, in the filtering mode, the filtering method comprises:
generating a first analog signal by sampling the input signal;
generating a first digital signal by converting the first analog signal;
generating a second digital signal by extracting the interference component from the first digital signal through a digital filter;
generating a second analog signal by converting the second digital signal;
generating a delayed first analog signal by delaying the first analog signal based on a delay caused in the second analog signal; and
generating an output signal by subtracting the second analog signal from the delayed first analog signal, and
wherein, in the correction mode, the filtering method comprises:
generating a standard signal that is a discrete time signal;
converting the standard signal into a fourth digital signal;
generating a delayed fourth digital signal by delaying the fourth digital signal by use of the digital filter;
generating a fifth analog signal by converting the delayed fourth digital signal;
generating a delayed fourth analog signal by delaying the fourth analog signal based on a delay in the fifth analog signal; and
correcting a filter characteristic of the digital filter to reduce a difference between frequency responses of digital signals respectively obtained by analog-to-digital converting the delayed fourth analog signal and the fifth analog signal.

12. The filter circuit of claim 1,
wherein the interference component is out of a signal band of a desired signal component to be processed.
